(19) United States
(12) Patent Application Publication
(10) Pub. No.: US 2005/0180086 A1
(43) Pub. Date: Aug. 18, 2005

(54) Removable, portable controlable power link for controlling and powering components of structures at an agribusiness

(76) Inventors: Stuart A. Schaefer, Pesotum, IL (US); Eugene B. Pollock, Assumption, IL (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 11/056,954

(22) Filed: Feb. 11, 2005

Related U.S. Application Data
(60) Provisional application No. 60/544,123, filed on Feb. 12, 2004.

(51) Int. Cl. H01L 29/00

(52) U.S. Cl. 361/154

(57) ABSTRACT

A control assembly is provided for a plurality of structures (such as grain bins, silos, dryers, hoppers, poultry houses, pig houses, etc.) at an agribusiness. Each structure includes one or more components to be controlled and a component cable to electrically connect the component to a source of power. The control assembly includes a mount for each structure and a control/power assembly which can be mounted to the mounts of the individual structures. The mount is fixedly mountable to a surface on or adjacent the structure and includes a bracket and an electrical outlet connected to a source of electricity. The control/power assembly includes a housing containing control circuitry, a plurality of component outlets each of which is electrically connected to a specific control circuit to receive the component cable of the structure; a connector for electrically connecting the control/power to the mount outlet. The control/power assembly can be mounted to the mount and connected to the components and the source of electricity to operate the components of the particular structure. When operations at the structure are complete, the portable control/power assembly can be removed from the mount and either placed in a secure location or mounted to the mount of a different structure to operate the components of the different second structure.

### CROSS-REFERENCE TO RELATED APPLICATIONS

This application claims priority under 35 U.S.C. §119 to provisional application No. 60/544,123 filed Feb. 12, 2004, entitled Portable Control Panel And Associated Mounted Docking Station For Controlling And/Or Powering Electrically Operated Or Controlled Components Of Structures At An Agribusiness, and which is incorporated herein by reference.

### STATEMENT REGARDING FEDERALLY SPONSORED RESEARCH OR DEVELOPMENT

Not Applicable.

### BACKGROUND OF THE INVENTION

This invention relates to control panels for structures such as grain containers (e.g., bins, silos, dryers, hoppers, etc.) and production facilities (e.g., such as poultry houses, swine houses, etc.) and the like, and, in particular, to a control panel which can be moved between several different structures and a mount on or adjacent the structures to electrically connect the control panel to the structure.

An agribusiness, such as a farm, grain storage facility, etc. can have several structures stationed around the agribusiness. Such structures can include grain containers and production facilities. A grain container generally includes various electrically operated and/or controlled components, such as a sweeps, spreaders, stirring devices, loading/unloading equipment, fans, heaters, lights, etc. Different groupings of the electrically operated and/or controlled components or accessories can be added to the containers depending on the use to which the container will be put. Thus, different grain containers on a single agribusiness can have different groupings of components.

The agribusiness' production facilities, such as poultry houses, hog houses, etc. are also provided with electrically operated or controlled components. Such components include, but are not limited to, ventilation equipment, including fans and louvers, heaters, lighting, feed storage equipment, feed loading equipment, etc. As with grain storage containers, the combination of electrically operated or controlled components provided with a particular production facility will depend on the use to which the particular production facility is put.

The electrically operated and/or controlled components for the structures are operated by a control panel. Typically, each structure will have a control panel to operate all the components on that particular structure. Typically, different structures are not operated at the same times. Thus, for example, if grain containers are being loaded during harvesting, the grain containers will not all be loaded simultaneously. Rather, they will be loaded as grain is delivered to the container. Similarly, the grain within different containers will not be stirred, unloaded, etc. at the same time. Hence, the individual control units for the grain containers are not used frequently.

The structures can often be located remotely from a residence, making it difficult to monitor the structure. In such circumstances, it is difficult to prevent others from operating the structure. For example, it has been known for unauthorized personnel to operate and take the grain from a remote grain container. Additionally, because the control box remains with the structure, insects can build nests in the control box and moisture and dirt can get into the control box, all of which can be detrimental to the control and power circuits contained within the control box. Lastly, because the control box is fixed relative to the structure, should the control box need repairs (i.e., should a board need to be replaced), the control box is difficult to work on.

It would be desirable to provide not only a control box which is removably connected to the structure, but to provide a single control box that can be connected to different structures, to control the components on each of the different structures.

### BRIEF SUMMARY OF THE INVENTION

A control/power assembly or link is provided for a plurality of structures, such as grain containers (e.g., grain bins, silos, dryers, hoppers, etc.) or production facilities (e.g., poultry houses, pig houses, etc). Each structure includes one or more electrically operated and/or electrically controlled components to be controlled and a component cable to electrically connect the component to a source of power. The control assembly includes a common mount for each structure and a control/power assembly which can be mounted to the mounts of the individual structure. The mount is fixedly positioned proximate the structure at a position to enable the operator to observe the operation of the component.

The mount includes a bracket and an electrical outlet connected to a source of electricity. The electrical outlet can be on the surface of the structure, and hence need not be part of the mount itself. The control/power assembly includes a housing containing control circuitry and load circuitry, a plurality of component outlets each of which is electrically connected to a specific control or load circuit and receives a component cable, and a connector for electrically connecting the control/power assembly to the mount outlet. The control/power assembly connector can include a connector cable which is removably connectable to the mount outlet. Additionally, the control/power assembly connecter can include an outlet, in which case, the connector cable is also removably connectable to the control/power connector outlet. The control/power assembly can be mounted to the mount and connected to the components and the source of electricity to power and control the components of the particular container or production facility. When operations at the structure are complete, the portable control/power assembly can be removed from the mount and either placed in a secure location or mounted to the mount of a structure to operate the components of the different second structure.

### BRIEF DESCRIPTION OF THE SEVERAL VIEWS OF THE DRAWINGS

FIG. 1 is a schematic of a farm showing grain containers located thereon;

FIG. 1A is an schematic elevational view of containers equipped with various components to be controlled;

FIG. 1B is a top plan schematic view showing the containers with the components to be controlled.

FIG. 2 is a perspective view of an illustrative control assembly of the present invention positioned on a mount on a grain container;

FIG. 2A is a front elevational view of the control assembly;

FIG. 2B is a side elevational view of the control assembly;

FIG. 3 is a front elevational view of an illustrative docking panel or station of the present invention;

FIG. 4 is a top plan view of the docking panel;

FIG. 5 is a side elevational view of the docking panel;

FIG. 6 is a perspective view of an illustrative control panel enclosure of the present invention;

FIG. 7 is a front elevational view of an illustrative control panel back plate of the present invention;

FIG. 8 is a top plan view of the control panel back plate;

FIG. 9 is a side elevational view of the control panel back plate; and

FIG. 10 is a back elevational view of the control panel pack plate;

Corresponding reference numerals will be used throughout the several figures of the drawings.

### DETAILED DESCRIPTION OF THE INVENTION

The following detailed description illustrates the invention by way of example and not by way of limitation. This description will clearly enable one skilled in the art to make and use the invention, and describes several embodiments, adaptations, variations, alternatives and uses of the invention, including what we presently believe is the best mode of carrying out the invention. Additionally, it is to be understood that the invention is not limited in its application to the details of construction and the arrangements of components set forth in the following description or illustrated in the drawings. The invention is capable of other embodiments and of being practiced or being carried out in various ways. Also, it is to be understood that the phraseology and terminology used herein is for the purpose of description and should not be regarded as limiting.

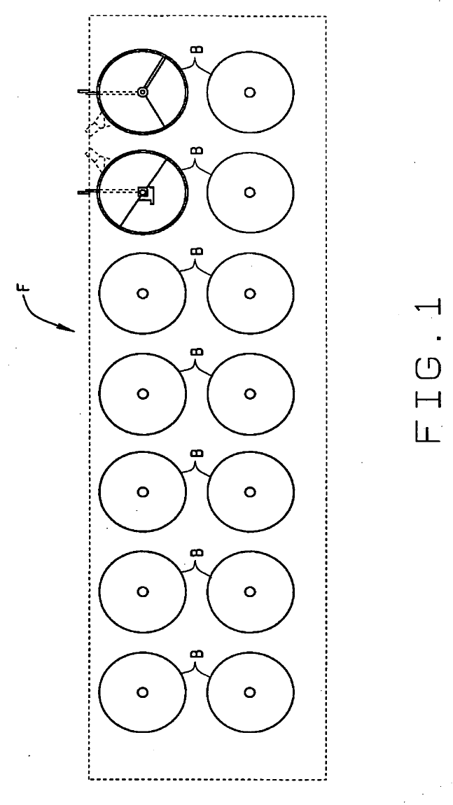

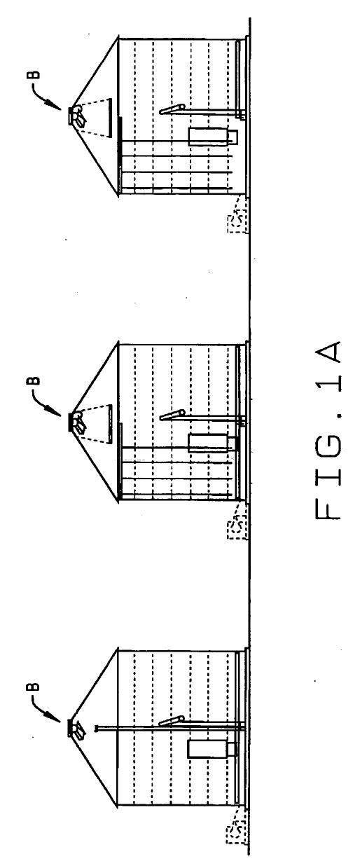

A farm installation F is shown schematically in FIG. 1. The farm F includes a plurality of structures, such as grain containers B (e.g., bins, silos, dryers, hoppers, etc.) and production facilities (e.g., poultry houses, pig houses, etc). The structures, such as the grain containers B, may be remotely located relative to a farmstead or other control center for the farm. For example, it is not uncommon to have grain containers in a remote field. Structures, such as grain containers B, may also be located at a commercial enterprise, such as a grain elevator. The structures are each connected to a source of electricity and each includes various electrically operable or controllable components. For example, as shown in FIGS. 1A and 1B, the containers B can be equipped with grain spreaders, stirrers, heater units including fans, loading and unloading systems, and/or recirculators. Bins can also be provided with lighting and electrical outlets to which other portable equipment, such as power tools, can be connected. Poultry and pig houses can be provided with heaters, fans, ventilation equipment, feed handling equipment as well as lighting and electrical outlets to which other portable equipment, such as power tools, can be connected. As is known, no single structure will necessarily include all the noted components. Additionally, the mix of components included on the structures may vary from structure to structure. Thus, for example, depending on what a container B is to contain, and the type of container, one container may, for example, contain a recirculator or stirring device and other associated drying equipment, while another container may, for example, contain a spreader and aeration equipment.

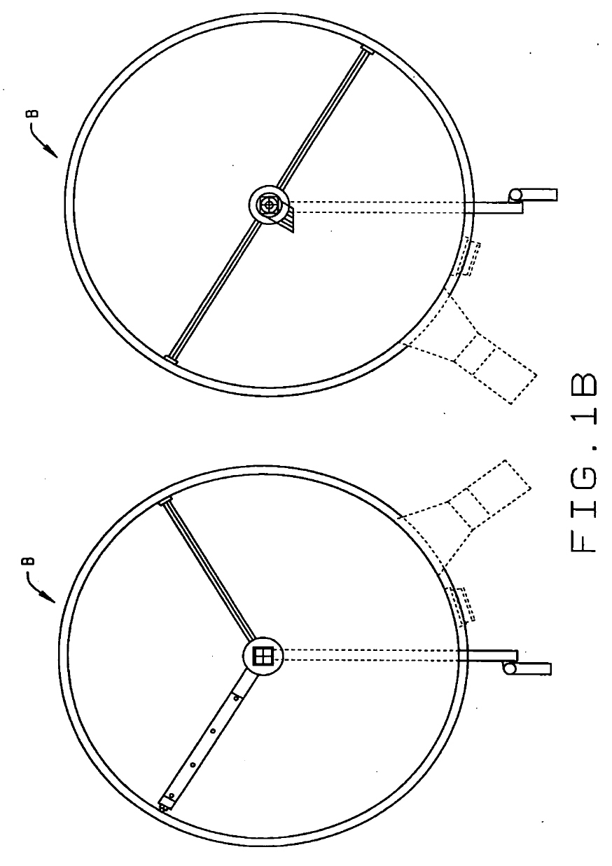

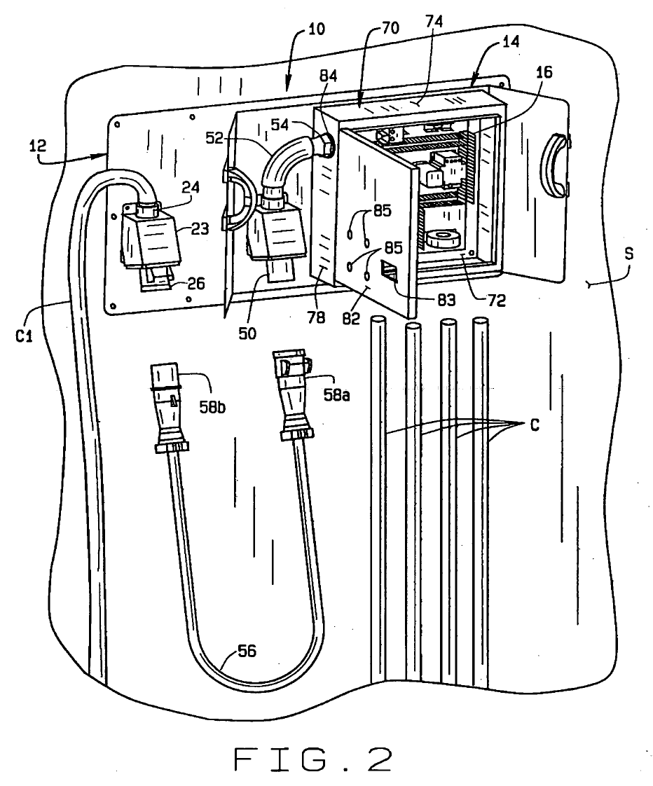

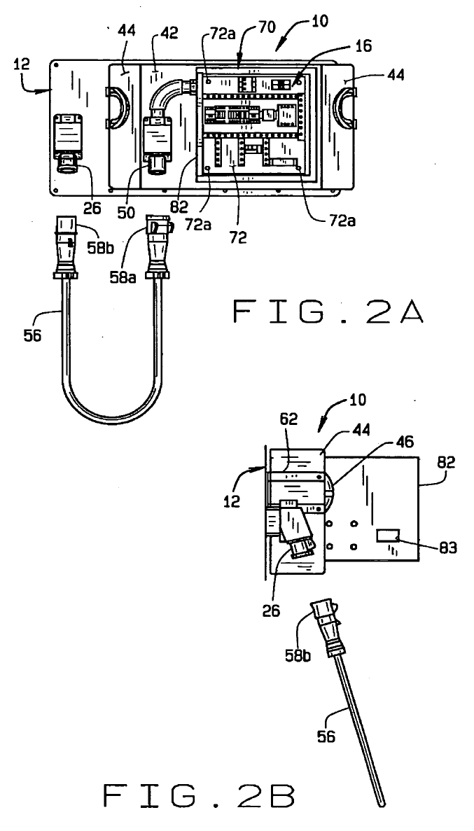

The invention is described in more detail with respect to the use of the invention on grain containers. However, the applicability of the invention to other agricultural structures, such as production facilities, will be apparent to those skilled in the art. Turning to FIG. 2, each container B includes a sidewall S. Electrical cables C extend from the sidewall S, there being one electrical cable for each component of the container to be controlled. The cables C are provided with connectors or plugs at their free ends. The container additionally includes an electrical cord C1, which may be encased in a conduit, which is connected to a source of electricity. To control the components of the container B, a control assembly 10 is positioned adjacent to the container. In FIG. 2, the control assembly is shown mounted on the container. However, depending on the components being powered and/or controlled, the control assembly 10 could be positioned, for example, on a pedestal adjacent to the container, or even on the component itself (i.e., on unloading equipment). It is, however, preferable that the control assembly 10 be positioned such that the equipment and operation being controlled can be observed and/or monitored by the operator. Thus, for example, if unloading equipment is being operated, the control/power assembly 10 is preferably positioned adjacent a door to the bin, such that the grain within the bin can be monitored. Positioning of the control/power assembly on the structure can also allow for easier monitoring, for example, of a truck being filled with grain.

The control/power assembly 10 includes a mount 12 and a control/power assembly or power link 14 which is removably mountable to the mount 12. The mount 12, as noted, is positioned at a desired position on or adjacent the container B. There is at least one mount 12 on each container B. Depending on the number of components on the container B or the position of the components on the container B, there could be more than one mount on the container B.

The control/power assembly 14 includes a controller 16. The controller 16, as known, contains load and control circuits for the different components to be powered and/or controlled. Depending on the number of different components represented by the plurality of containers, and the number of components on each container, a single farm may need only one control/power assembly 14 to power and/or control all the components of all the containers. In this instance, as will be described below, the control/power assembly will be mounted to the mount of a desired container, and the desired component(s) of the container will be operated. When completed, the control/power assembly can be removed from the mount. In this state, the components are not connected to a source of power, and hence are inoperable. When desired, the control/power assembly 14 can be mounted to the mount of a different container, to control desired components on that second container.

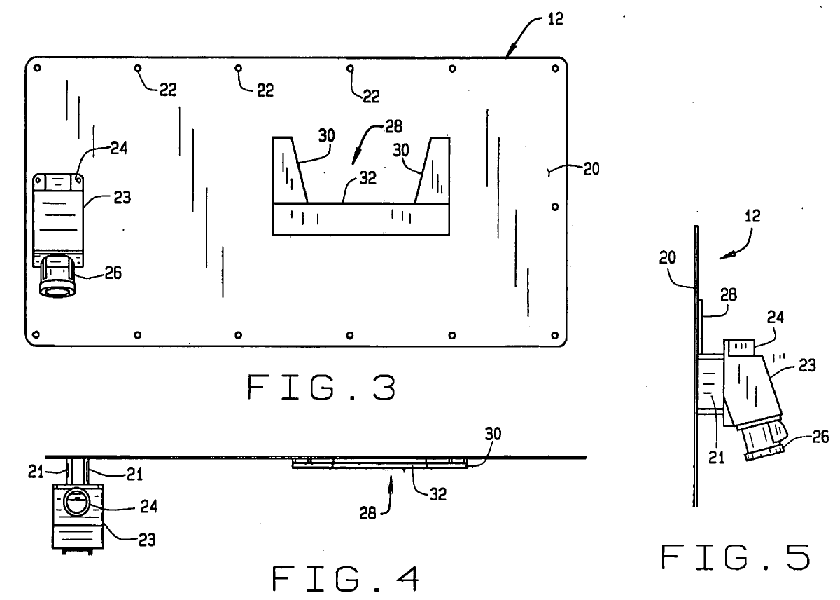

Turning to FIG. 3, the mount 12 includes a base plate 20. The plate 20 has a plurality of holes 22 through which bolts, rivets, or other fasteners extend to fix the plate 20 to the surface to which the mount is to be mounted. As noted, in the drawings, the surface is the container sidewall S. An electrical box 23 is mounted to the plate 20, preferably off to one side of the plate. The box 23 is spaced from the plate 20 by legs 21, as seen in FIG. 4. The box 23 includes a collar 24 which receives the container electrical cable C1 to connect the box 23 to the source of electricity. The box 23 also includes an outlet 26, which, as will become apparent, places the controller 16 in communication with the source of electricity. Lastly, the plate 20 includes a bracket 28. The bracket 28 is shown to include a pair of legs 30 and a web 32 which extends between the legs. The legs 30 space the web 32 from the surface of the plate 20, such that there is a gap between the plate 20 and the web 32.

The control/power assembly 14 (FIG. 2) includes a back plate 40 (FIG. 7). The back plate 40 includes a plate base 42. The base plate 42 is shown to be generally rectangular in shape, but could be formed in any desired shape. The base plate 42 has a side-to-side width less than the side-to-side width of the docking panel plate 20. A wing 44 extends outwardly from the opposite sides of the base plate 42. As seen, the wings 44 extend at an oblique angle to the base plate 42. Handles 46 extend generally perpendicularly to the wings 44.

The front of the base plate 42 is provided with an electrical box 48, which is preferably located near a side edge of the base plate 42. The electrical box 48 is provided with an outlet 50 on one side, and an electrical conduit 52 on another side. The conduit 52 has an electrical connector 54 at its free end. Turning back to FIGS. 2 and 2A, an electrical connector cord 56 has plugs 58a,b at its opposite ends. The plug 58a is adapted to be received in the outlet 50 of the control assembly back plate 40 and the plug 58b is adapted to be received in the outlet 26 of the mount 12. Importantly, the plug 58b is removably connected to the outlet 26. Preferably, the plug 58a is also removably connected to the outlet 50. As can be appreciated, the connector cord 56 electrically connects the control/power assembly 14 (and hence the load and control circuits) to the source of electricity. In lieu of the power cord, the mount outlet 26 and the control/power assembly outlet 50 could be configured as a plug and an outlet, respectively, such that when the control/power assembly 14 is mounted on the mount, the control/power assembly outlet (or plug) would be electrically connected to the mount plug (or outlet).

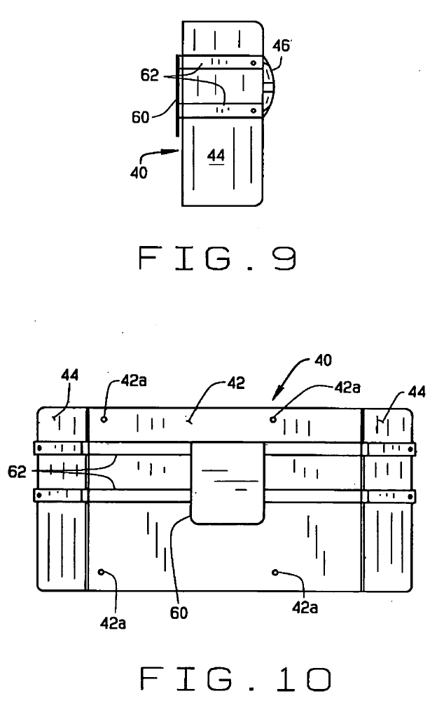

Returning to FIGS. 7-10, the back of the control assembly back plate 40 is provided with a bracket engaging member which is in the form of a plate 60 connected at its top to the back surface of the base plate 42 of the back plate 40. The bracket plate 60 has a width sized to be received in the gap defined by the bracket 28 on the mount 12, such that the plate 60 can be easily slid into and out of the bracket 28, while minimizing any side-to-side motion of the control/power assembly 14 when mounted to the mount 12. As can be appreciated, the use of the plate 60 and the bracket 28 allows for the control assembly to be mounted to the structure without the use of tools. That is, no screws, bolts, etc. need be tightened or loosened to connect the control assembly to the bracket or remove the control/power assembly from the bracket. Hence, the control/power assembly can be easily and quickly mounted on the bracket 28 and removed from the bracket 28.

A pair of straps 62 extends across the back of the back plate 40, from the edge of one wing 44 to the edge of the opposite wing 44. The straps 62 are secured to the back plate 40, for example, by welding. The straps 62 are spaced apart from each other a distance generally equal to the height of the handles 46. The bracket engaging plate 60 is fixed to both of the straps.

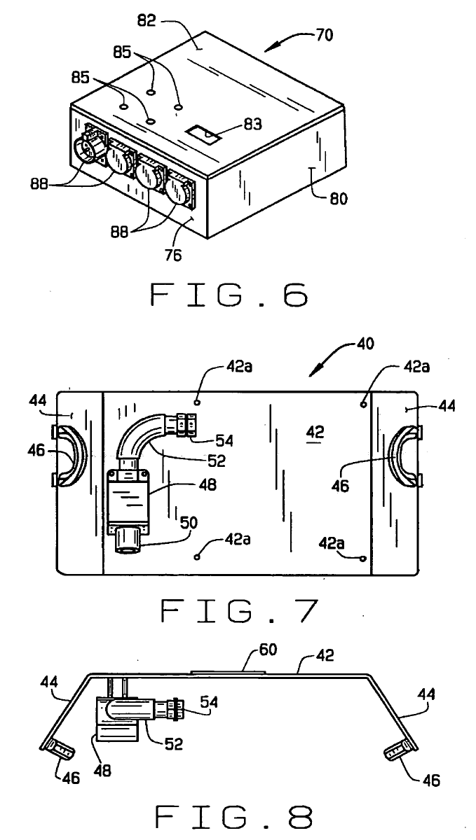

The control/power assembly 14 also includes a housing 70 which is shown more clearly in FIGS. 2, 2A, and 6 which is mounted to the back plate panel 42. As best seen in FIG. 2A, the housing 70 is spaced above the bottom edge of the back panel plate 42. The housing 70 has a back surface 72, a top surface 74, a bottom surface 76, a first side surface 78, a second side surface 80, and a cover 82. The housing 70 is mounted to the back plate back panel 42 by way of fasteners which extend through four openings 72a (FIG. 2A) in the housing back surface 72 and corresponding openings 42a (FIG. 7) in the back plate panel 42. Because fasteners are used to secure the housing 70 to the back plate 40, the housing can be removed from the back plate 40.

The various surfaces and the cover define an enclosure in which the controller 16 is contained. The cover 82 is preferably hingedly connected to one of the container walls (i.e., the top surface, bottom surface, or side surfaces) to enable access to the interior of the container. The cover 82 is provided with a handle 83 in the form of an opening which an operator can use to open the cover. Additional openings 85 are formed on the front cover for switches, signal lights, etc.

The controller 16 includes a circuit board which is mounted to the back surface 72 of the housing 70. The circuit board, in turn, contains the load and control circuits for the various components on the containers. As can be appreciated, the exact circuitry on the board of the controller 16 can vary depending on the type of equipment that will be controlled. As will be described below, the controller 16 is connected to the electrical supply for the structure, and this power supply is used to provide main power for the components (i.e., power to drive a motor) as well as the power for the control circuits for the components (i.e., the activation and deactivation of the motor, for example). Hence, the control assembly 14 is a link between the components of the structure and the structure's power supply and includes both the load circuit and the control circuit for the components.

The housing first side surface 78 includes a hole 84 (FIG. 2) to which the back plate conduit connector 54 can be secured. The wires contained within the back plate conduit 52 can then be connected to the control board within the housing. The connection between the wires contained within the conduit 52 and the circuit board can either be a permanent connection (i.e., the wires can be hardwired to the circuit board) or a connector can be provided to removably connect the wires of the conduit 52 to the circuit board.

One of the surfaces is provided with component outlets 88 (FIG. 6), which are shown to be positioned on the housing bottom surface 76 (but could be positioned on other surfaces as well). The outlets 88 are connected to the circuit board of the controller 16, there being one outlet for each of the control and/or load circuits on the circuit board. The outlets 88 receive the plugs of the component cables C. Hence, a particular outlet is electrically connected to, and controlled by a particular control or power circuit on the board. Further, there is one outlet 88 for each element or component to be operated. For example, a bin sweep may have two motors to be controlled. Hence, there would be two cables C (FIG. 2) corresponding to the bin sweep, two control and/or power circuits on the controller 16 for the sweep, and two outlets 88 for the bin sweep. Preferably, the outlets are provided with hinged covers or with collars, as shown in FIG. 6 to protect the outlets.

The component cables C (FIG. 2) are connected to the component outlets. The housing is provided with some type of indicia to indicate which component cable C is to be connected to which component outlet 88. The indicia can take the form of colors—different colors can be provided for different components, and the operator would then match the component cables C to the component outlets 88 by color. Preferably, however, the indicator is shape-based, such that only a particular component cable C can be connected to a particular component outlet 88.

In use in an agribusiness (such as a farm), the various containers (i.e., containers, silos, dryers, hoppers, etc.) on the site of the agribusiness are each provided with at least one of the mounts 12. Due to size limitations of the housing 70, only a certain number of components can be connected to the housing station. Hence, if the container has, for example, more than four or six components which need to be controlled, two or more mounts will be fixed to the container. The cables C (FIG. 2) for the components to be controlled are available adjacent the mount 12. Additionally, if components that need to be observed are on opposite sides of the container, such that an operator could not observe one of the components if only a single mount were provided, an additional mount can be provided. When the components of the container are to be operated, an operator will place the control/power assembly 14 on the mount using the mount bracket 28 and the bracket engaging member 60 on the control/power assembly back plate 40. After the control/power assembly 14 has been mounted on the mount, the operator will connect the control/power outlet 50 to the mount outlet 26 with the cord 56. As discussed above, this will connect the control panel board to the source of electricity for the container. The operator can then connect the component cables C to the appropriate outlets. Although the method has been described that the controller is connected to the source of electricity prior to connecting the component cables C to the controller (via the controller outlets 88), this can be done in any desired order. Because the housing 70 includes control circuits for the components of several different containers, when the cables C of the particular container are connected to the outlets 88, there may be control circuits (and hence component outlets 88) for which there is no corresponding component or component cable C on the particular container B. With the controller 16 now electrically connected to the source of electricity and to the components which will be operated by the controller, the operator can operate the components via the control/power in a known manner, to operate and control the components of the container B.

When the operation at the particular container is completed, the electrical cables C can be disconnected from the housing 70, and the cord 56 can be disconnected from either or both of the outlets 26 and 50. The control/power assembly can then be removed from the mount 12. After the control/power assembly has been removed from the mount 12, the control/power assembly can be connected to a mount of a different container (following the procedure noted above) or the control/power assembly 14 can be put away, for example, in an office. Because the wings 44 extend from the back panel 44 at an oblique angle, when the control/power assembly 14 is dismounted from a bin B, the control/power assembly can stand. As noted above, the bottom of the housing 70 is spaced above the bottom edge of the back plate panel 42. Hence, when the control/power assembly 14 is placed on a surface standing on the back plate 42 and wings 44, the outlets 88 will be spaced from the surface upon which the control/power assembly is placed, and will be at least partially protected from the surface.

As can be appreciated, the mount 12 is a common mount (i.e., the same mount 12 is provided on each structure having components to be controlled. The control assembly or power link 14 is easily and quickly mounted or placed on the mount 12 without the use of tools. Additionally, the connections between the component cables C and the control assembly 14 and the connection between the control assembly and the structure power supply are made by way of plugs, which can be connected and disconnected, again without the use of tools. Thus, the control and power panel 14 can be quickly and easily connected to a structure to enable operation of the structure's components. When operations at the structure are finished, the control/power panel 14 can be quickly and easily disconnected from the power supply and component cables, and can be quickly and easily removed from the mount 12. The ability to remove the control/power panel from the mount 12 has several advantages. When the control/power assembly 14 is not connected between the components and the power source, not only is there no power to operate the components in the structure, there are no controls to activate the components in the structure. Hence, the components cannot be operated. Therefore, the ability to remove the control/power assembly from the structure (e.g., grain bin, production facility, etc.) will prevent unauthorized operation of components of the structure. Further, because the control/power assembly is removable from the mount, any repairs that may have to be performed to the control/power assembly can be done more easily. Additionally, because the control/power assembly can be stored inside, it will not be exposed to the weather (i.e., extreme temperatures, rain, wind, dirt, snow, etc.), and insects will not be able to enter the housing 70. Lastly, because the structures at a particular agribusiness will only use a predetermined universe of components, and because the various structures are not generally operated at the same time, the agribusiness may need only a single control/power assembly for all the structures at the agribusiness. If one or more structures are generally operated concurrently, then the agribusiness can be provided with a second (or third) control/power assembly, as may be necessary. However, the agribusiness will not need an individual controller for each structure at the agribusiness. Thus, when operations at one structure are complete, the control/power link 14 can be moved from that structure to a different structure to enable operations at that second structure. This reduces the redundancy of controllers that currently exists in agribusinesses which have two or more structures with electrically powered and/or controlled components.

As various changes could be made in the above constructions without departing from the scope of the invention, it is intended that all matter contained in the above description or shown in the accompanying drawings shall be interpreted as illustrative and not in a limiting sense. Although the housing 70 and back plate 40 are described as independent pieces, the back plate 40 could be formed into the housing 70. For example, the housing back surface 72 could be enlarged to additionally form the back plate back panel 42. The control/power assembly can be provided to control some, rather than all, of the components of a structure. For example, if a bin is provided with a heater, recirculator, or other grain conditioning components, the bin can be provided with a permanent controller for such grain conditioning components, and the removable docking unit 14 can be used to control grain loading and unloading equipment. The outlet 26 on the mount 12 could be adjacent the mount 12 (i.e., extend from the surface S), and hence, would not be part of the mount 12. Although the component cables C are disclosed to come from the structure, the component cables could, instead be part of the power/control assembly 14, and the structure could be provided with plugs. In this instance, the component cables would be connected to the plugs of the structure. In a further alternative, both the structure and the power/control assembly 14 could be provided with plugs, and the component cables C would be provided with connectors on their opposite ends to allow for removably connecting the component cables C to both the power/control assembly and the housing. This would allow for the component cables to be removed from the structure when the structure components are not being operated for storage or for use with another structure. These examples are merely illustrative.

1. A control assembly for driving and/or controlling electrically powered and/or controlled components associated with structures at an agribusiness; the control assembly including:
a mount fixed to a surface on or adjacent said structure at an appropriate location to facilitate the ease and control of the equipment by an operator; the mount comprising a bracket and an electrical connector; said electrical connector being connectable to a source of electricity and including a mount electrical outlet;
a control/power assembly removably mountable to the mount; the control/power assembly comprising:
a housing having a back surface, a front surface, top and bottom surfaces, and side surfaces defining an enclosure; load and control circuitry contained within the enclosure for powering and controlling at least one of the components of the structure to which the control/power assembly is to be mounted; and a component outlet electrically connectable to one or more of the control circuits and/or load circuits;
a bracket engaging member positioned on the housing shaped to engage the mount bracket to removably mount the control/power assembly to the mount; and
an electrical connector operatively and electrically connected to the controller and removably connectable to said mount electrical outlet.

2. The control assembly of claim 1 wherein said electrical connector comprises an electrical connecting cord which is removably connectable at a first end to said mount electrical outlet.

3. The control assembly of claim 2 wherein said control/power assembly includes a power outlet; said connector cord being removably connectable at a second end to said control/power assembly power outlet.

4. The control assembly of claim 1 wherein said control/power assembly includes a back plate; said bracket engaging member being mounted to said back plate; said controller housing being separate from, and mounted to, said back plate.

5. The control assembly of claim 4 wherein the back plate includes at least one handle thereon.

6. The control assembly of claim 5 wherein the back plate includes a pair of opposed side members, extending outwardly from the back plate, there being a handle on each side member.

7. The control assembly of claim 1 wherein the control circuitry includes a set of control and/or load circuits to control and/or power a desired set of components, and wherein, the set of control and/or load circuits is greater than the number of components to be controlled and/or powered at a particular structure; whereby, a single control/power assembly can be used to power and control components on a number of different structures.

8. A power and control system for individually powering and controlling an electrically operated and/or controlled component of a structure at an agribusiness; each structure being connected to a source of electricity and including one or more controllable components and an electrical cable for each controllable component; said system comprising;
a plurality of common mounts, there being at least one mount fixed on or adjacent each structure of the plurality of structures; each said mount including a mounting bracket;
an electrical outlet connectable to said source of electricity at each structure; and
a control/power assembly; said control/power assembly comprising a bracket engaging member to removably mount the control/power assembly to the mount; a control unit comprising load and/or control circuitry for the components of the plurality of structures; an electrical connector operatively connected to said control circuitry and being removably connectable to said mount electrical outlet; and a plurality of component outlets to removably receive controllable component cables of the structures.

9. The control system of claim 8 comprising a single control/power assembly for the plurality of structures.

10. The control system of claim 8 wherein the control/power assembly comprises a control housing and a backing member; said control housing containing said load and/or control circuitry and said plurality of component connectors; said backing including said bracket engaging member.

11. The control system of claim 10 wherein said control/power assembly electrical connector comprises an electrical outlet on said backing member and an electrical cord removably connectable at its opposite ends to said control/power assembly outlet and said mount electrical outlet; said control/power assembly electrical outlet being in electrical communication with said control circuitry.

12. A control system for individually powering and/or controlling an electrically operated and/or controlled component of a structure at an agribusiness; each structure being connected to a source of electricity and including one or more controllable components and an electrical cable for each controllable component; said control system comprising;
a control assembly comprising load and/or control circuitry for at least some the components of two or more of the structures of the agribusiness; means for electrically connecting said components to said control assembly; means for connecting said control assembly to said source of electricity; and means for removably mounting said control assembly to said structures.

13. The control system of claim 12 wherein said means for removably mounting said control assembly to said structures comprises a mount on said structure and a bracket on said control assembly.

14. The control system of claim 13 wherein said mount includes an electrical outlet which is electrically connected to the source of electricity for said structure; said means for electrically connecting said comprising an electrical cord adapted at a first end to be removably connectable to said mount outlet and in electrical communication with said load and/or control circuitry.

15. The control system of claim 14 wherein said control assembly comprises a housing and a control assembly outlet; said control assembly outlet being in electrical communication with said load and/or control circuitry; said electrical cord being adapted an a second end to be removably connectable to said control assembly outlet.

16. The control system of claim 12 wherein means for electrically connecting said components to said control assembly includes two or more component outlets; each component outlet of said control assembly being in electrical communication with a separate load and/or control circuit of said control assembly; said component outlets including means for differentiating said compound outlets from each other.

17. A method for controlling and/or powering selected components of selected structures in an agribusiness; each said selected structure including or being connected to a source of electricity, having a mounting member thereon or adjacent thereto and including at least one electrical connector for each selected component of the selected structure to be controlled and/or powered; the method comprising:
removably mounting a control assembly on or adjacent said selected structure;
removably connecting said control assembly to said source of electricity for said selected structure; and
removably connecting at least one electrical connector for each selected component of said selected structure to be powered and/or controlled by said control assembly to said control assembly.

18. The method of claim 17 wherein, after operations at a selected structure are completed, said method further comprises disconnecting said electrical cables from the control assembly, disconnecting said control assembly from said source of electricity; and removing said control assembly from said mounting member.

19. The method of claim 17 wherein said step of mounting said control assembly to said mounting member is performed without the use of tools.
